(19) United States
(12) Patent Application Publication
(10) Pub. No.: US 2008/0277716 A1
(43) Pub. Date: Nov. 13, 2008

(54) SEMICONDUCTOR DEVICE

(76) Inventors: Daisuke NISHIDA, Yokkaichi-shi (JP); Akihito YAMAMOTO, Naka-gun (JP); Yoshio OZAWA, Yokohama-shi (JP); Katsuaki NATORI, Yokohama-shi (JP); Katsuyuki SEKINE, Yokohama-shi (JP); Masayuki TANAKA, Yokohama-shi (JP); Ryota FUJITSUKA, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/113,367

(22) Filed: May 1, 2008

(30) Foreign Application Priority Data
May 7, 2007 (JP) 2007-122429

(51) Int. Cl. H01L 29/788

(52) U.S. Cl. 257/321; 257/E29.3

(57) ABSTRACT

A semiconductor device includes a semiconductor substrate having a device formation region, a tunnel insulating film formed on the device formation region, a floating gate electrode formed on the tunnel insulating film, isolation insulating films which cover side surfaces of the device formation region, side surfaces of the tunnel insulating film, and side surfaces of a lower portion of the floating gate electrode, an inter-electrode insulating film which covers an upper surface and side surfaces of an upper portion of the floating gate electrode, and a control gate electrode formed on the inter-electrode insulating film, wherein upper corner portions of the floating gate electrode are rounded as viewed from a direction parallel with the upper surface and the side surfaces of the upper portion of the floating gate electrode.

### CROSS-REFERENCE TO RELATED APPLICATIONS

This application is based upon and claims the benefit of priority from prior Japanese Patent Application No. 2007-122429, filed May 7, 2007, the entire contents of which are incorporated herein by reference.

### BACKGROUND OF THE INVENTION

1. Field of the Invention

This invention relates to a semiconductor device.

2. Description of the Related Art

Nonvolatile semiconductor memory devices represented by NAND memories have a tunnel insulating film formed on a semiconductor substrate, a floating gate electrode formed on the tunnel insulating film, an inter-electrode insulating film formed on the floating gate electrode, and a control gate electrode formed on the inter-electrode insulating film (for example, refer to Jpn. Pat. Appln. KOKAI Pub. No. 9-134973).

However, with miniaturization of semiconductor devices, there are caused problems relating to leak current and breakdown voltage of the inter-electrode insulating film. However, in prior art, it cannot be said that proper measures are taken against the problems relating to leak current and breakdown voltage of the inter-electrode insulating film.

### BRIEF SUMMARY OF THE INVENTION

A semiconductor device according to a first aspect of the present invention comprises: a semiconductor substrate having a device formation region; a tunnel insulating film formed on the device formation region; a floating gate electrode formed on the tunnel insulating film; isolation insulating films which cover side surfaces of the device formation region, side surfaces of the tunnel insulating film, and side surfaces of a lower portion of the floating gate electrode; an inter-electrode insulating film which covers an upper surface and side surfaces of an upper portion of the floating gate electrode; and a control gate electrode formed on the inter-electrode insulating film, wherein upper corner portions of the floating gate electrode are rounded as viewed from a direction parallel with the upper surface and the side surfaces of the upper portion of the floating gate electrode.

A semiconductor device according to a second aspect of the present invention comprises: a semiconductor substrate having a device formation region; a tunnel insulating film formed on the device formation region; a floating gate electrode which is formed on the tunnel insulating film and has a lower portion and an upper portion having a width smaller than a width of the lower portion; isolation insulating films which cover side surfaces of the device formation region, side surfaces of the tunnel insulating film, and side surfaces of the lower portion of the floating gate electrode, and has an upper surface located higher than a boundary between the lower portion and the upper portion of the floating gate electrode; an inter-electrode insulating film which covers an upper surface and side surfaces of the upper portion of the floating gate electrode; and a control gate electrode formed on the inter-electrode insulating film.

### BRIEF DESCRIPTION OF THE SEVERAL VIEWS OF THE DRAWING

FIGS. 1 to 4 are cross-sectional views illustrating a basic manufacturing process of a semiconductor device according to first and second embodiments of the present invention.

FIGS. 5 and 6 are schematic cross-sectional views illustrating details of a method of forming an inter-electrode insulating film according to the first embodiment of the present invention.

FIGS. 7A to 7D are schematic cross-sectional views of various basic shapes of a floating gate electrode according to the first embodiment of the present invention.

FIG. 8 is a diagram illustrating a measurement result of the semiconductor device according to the first embodiment of the present invention.

FIG. 9 is a diagram illustrating a measurement result of the semiconductor device according to the first embodiment of the present invention.

FIGS. 10 to 14 are schematic cross-sectional views illustrating details of a method of forming an inter-electrode insulating film and the like according to the second embodiment of the present invention.

FIG. 15 is a schematic cross-sectional view of a modification of the second embodiment of the present invention.

FIG. 16 is a schematic cross-sectional view of another modification of the second embodiment of the present invention.

FIG. 17 is a diagram illustrating measurement results of the semiconductor device according to the second embodiment of the present invention and a semiconductor device according to a comparative example thereof.

FIG. 18 is a diagram illustrating measurement results of the semiconductor device according to the second embodiment of the present invention and the semiconductor device according to the comparative example thereof.

### DETAILED DESCRIPTION OF THE INVENTION

Embodiments of the present invention are explained below with reference to drawings.

(Embodiment 1)

A semiconductor device (nonvolatile semiconductor memory device) according to a first embodiment of the present invention is described below. The semiconductor device is applied to, for example, NAND memories.

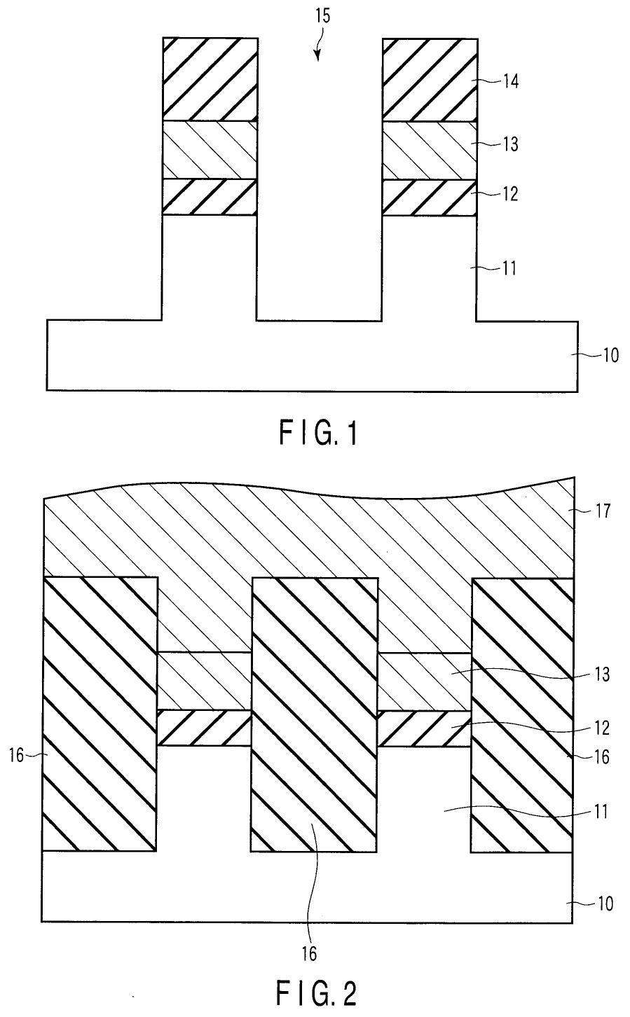

FIGS. 1 to 4 are cross-sectional views illustrating a basic manufacturing process of the semiconductor device according to the first embodiment, in the word line direction (channel width direction).

First, as illustrated in FIG. 1, a silicon oxide film having a thickness of about 1 to 15 nm is formed as a tunnel insulating film 12 on a p-type silicon substrate (semiconductor substrate) 10. Next, an n-type polysilicon film having a thickness of about 10 to 200 nm is formed as a first floating gate electrode film 13 on the tunnel insulating film 12. Then, a mask film 14 is formed on the first floating gate electrode film 13. Further, a photoresist pattern (not shown) extending in a first direction (bit line direction) is formed on the mask film 14 by photolithography. With the photoresist pattern used as a mask, the mask film 14, the first floating gate electrode film 13, the tunnel insulating film 12 and the silicon substrate 10 are etched. Thereby, a device formation region 11 is formed in the silicon substrate 10, and an isolation trench 15 which defines the device formation region 11 is formed.

Next, as illustrated in FIG. 2, a silicon oxide film having a thickness of about 200 to 1500 nm is formed as an isolation insulating film 16 on the whole surface, and thereby the isolation trench 15 is filled with the isolation insulating film 16. Further, the isolation insulating film 16 is flattened by CMP (chemical mechanical polishing), and thereby the upper surface of the mask film 14 is exposed. After the mask film 14 is removed, an n-type polysilicon film is formed as a second floating gate electrode film 17 on the whole surface.

Next, as illustrated in FIG. 3, the second floating gate electrode film 17 is flattened by CMP, and thereby the upper surface of the isolation insulating film 16 is exposed. Then, the isolation insulating film 16 is subjected to etch back, and thereby the side surfaces of the second floating gate electrode film 17 are exposed. The first floating gate electrode film 13 and the second floating gate electrode film 17 are referred to as floating gate electrode film 18 in combination hereinafter.

Next, as illustrated in FIG. 4, an inter-electrode insulating film 20 is formed on the whole surface. A method of forming the inter-electrode insulating film 20 will be described later. Then, a control gate electrode film 21 is formed on the inter-electrode insulating film 20. Thereafter, a mask film (not shown) is formed on the control gate electrode film 21. Further, a photoresist pattern (not shown) extending in a second direction (word line direction) perpendicular to the first direction is formed on the mask film by photolithography. With the photoresist pattern used as a mask, the mask film (not shown), the control gate electrode film 21, the inter-electrode insulating film 20 and the floating gate electrode film 18 are etched. Thereby, patterns of the floating gate electrode 18 and the control gate electrode 21 are formed. Further, impurity elements are implanted into the silicon substrate 10, and thereby source/drain regions (not shown) are formed.

As described above, memory cells of the nonvolatile semiconductor memory device as illustrated in FIG. 4 are formed. Specifically, the tunnel insulating film 12, the floating gate electrode 18, the inter-electrode insulating film 20 and the control gate electrode 21 are successively stacked on the device formation region 11 of the silicon substrate 10, and a gate structure of a memory cell is formed thereby. Further, side surfaces of the device formation region 11, side surfaces of the tunnel insulating film 12, and side surfaces of a lower portion of the floating gate electrode 18 are covered with the isolation insulating film 16. The upper surface and side surfaces of an upper portion of the floating gate electrode 18 and the upper surface of the isolation insulating film 16 are covered with the inter-electrode insulating film 20. Although not shown in FIG. 4, upper corner portions of the floating gate electrode 18 are rounded as viewed from a direction parallel with the upper surface and side surfaces of the upper portion of the floating gate electrode 18 (the direction vertical to the surface of the drawing), as described later.

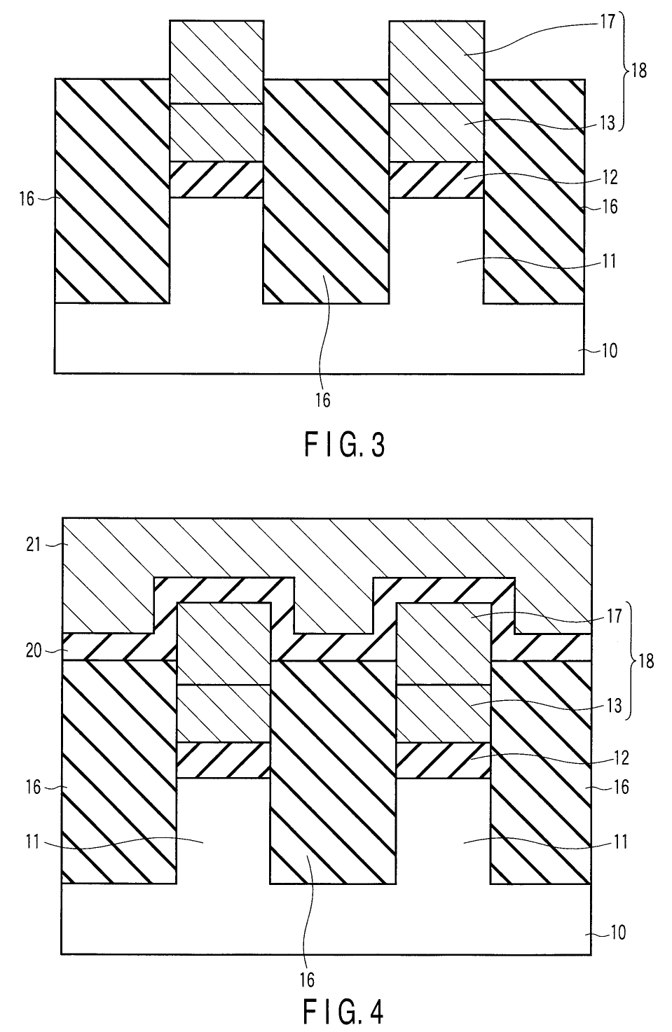

Next, details of a method of forming the inter-electrode insulating film 20 are explained with reference to cross-sectional views of FIGS. 5 and 6 (cross-sectional views in the word line direction).

After the step illustrated in FIG. 3, anisotropic plasma nitriding is performed as illustrated in FIG. 5. In other words, anisotropic plasma treatment is performed in an atmosphere including nitrogen (N). Specifically, the substrate temperature is set to 200 to 500° C., the pressure is set to 50 to 500 mTorr, and bias is applied to the substrate with an electric power of 10 to 800 W. By the anisotropic plasma treatment, the exposed surface of the floating gate electrode film 18 formed of polysilicon is nitrided, and a silicon nitride film 31 (predetermined insulating film) having a thickness of about 0.1 to 10 nm is formed. Further, the surface of the isolation insulating film 16 is also nitrided, and nitrogen is contained in the surface region of the isolation insulating film 16.

In the above anisotropic plasma treatment, nitrogen reaches the floating gate electrode film 18 mainly from a direction vertical to the upper surface of the floating gate electrode film 18. However, there is also nitrogen which reaches the floating gate electrode film 18 from the inclined direction. Therefore, in the upper corner portions of the floating gate electrode film 18, nitriding proceeds also in the horizontal direction in addition to the vertical direction. Further, since the electric field is concentrated on the upper corner portions of the floating gate electrode film 18 in the above anisotropic plasma treatment, nitrogen tends to be concentrated on the upper corner portions.

For the above reasons, in the above anisotropic plasma treatment, nitriding strongly acts on the upper corner portions of the floating gate electrode film 18. As a result, as illustrated in FIG. 5, the silicon nitride film 31 is formed thicker on the upper corner portions of the floating gate electrode film 18 than on other portions. Further, the upper corner portions of the floating gate electrode film 18 are rounded. However, since the silicon nitride film 31 is formed by nitriding the floating gate electrode film 18, upper corner portions of the silicon nitride film 31 are rounded less easily than the upper corner portions of the floating gate electrode film 18. Therefore, the radius of curvature of the upper corner portions of the floating gate electrode film 18 is larger than the radius of curvature of the upper corner portions of the silicon nitride film 31.

Further, for the above reasons, a portion of the silicon nitride film 31 which is formed on the side surfaces of the floating gate electrode film 18 is thinner than a portion of the silicon nitride film 31 which is formed on the upper surface of the floating gate electrode film 18. In addition, the thickness of the portion of the silicon nitride film 31 formed on the side surfaces of the floating gate electrode film 18 increases from below upward.

Next, as illustrated in FIG. 6, a metal oxide film (for example, an aluminum oxide film) 33 is formed on the silicon nitride film 31 and the isolation insulating film 16. Further, a silicon nitride film 34 is formed on the metal oxide film 33. Thereby, obtained is an inter-electrode insulating film 20 which is formed of a stacked film including the silicon nitride film 31, the metal oxide film 33, and the silicon nitride film 34. The radius of curvature of the upper corner portions of the floating gate electrode film 18 is larger than radius of curvature of upper corner portions of the inter-electrode insulating film 20 formed of the above stacked film.

After the inter-electrode insulating film 20 is formed as described above, the control gate electrode film 21 is formed on the inter-electrode insulating film 20 as illustrated in FIG. 4.

As described above, according to the first embodiment, the upper corner portions of the floating gate electrode 18 are rounded, as viewed from the direction parallel with the upper surface and side surfaces of the floating gate electrode 18 (the direction vertical to the surface of the drawing). Therefore, concentration of the electric field in the upper corner portions of the floating gate electrode 18 can be eased. Further, since the upper corner portions of the floating gate electrode 18 are rounded, the inter-electrode insulating film 20 (in particular, the silicon nitride film 31) has a sufficient thickness in the upper corner portions. Therefore, it is possible to effectively prevent increase in the leak current and decrease in the breakdown voltage of the inter-electrode insulating film 20. Consequently, it is possible to achieve increase in charge retention characteristic, and obtain a semiconductor device having excellent characteristic and reliability.

The above embodiment can be variously modified as mentioned below.

Although the inter-electrode insulating film 20 is formed of a stacked structure including the silicon nitride film 31, the metal oxide film 33, and the silicon nitride film 34 in the above embodiment, the inter-electrode insulating film 20 may be formed of other stacked structures. Any desired combination of silicon nitride films, silicon oxide films and metal oxide films can be used as the stacked structure. For example, a stacked structure obtained by stacking a silicon nitride film, a silicon oxide film, and a silicon nitride film in this order may be used as the inter-electrode insulating film 20. Further, a stacked structure obtained by stacking a silicon nitride film, a silicon oxide film, a metal oxide film, a silicon oxide film, and a silicon nitride film in this order may be used as the inter-electrode insulating film 20. Furthermore, a stacked structure obtained by stacking a silicon nitride film, a silicon oxide film, a silicon nitride film, a silicon oxide film, and a silicon nitride film in this order may be used as the inter-electrode insulating film 20. In these cases, the undermost silicon nitride film contacting the floating gate electrode 18 corresponds to the silicon nitride film 31. Further, the inter-electrode insulating film 20 may not be formed of a stacked structure, but may be formed of a single-layer structure of the silicon nitride film 31. These structures can also obtain the same effect as described above.

Further, although the silicon nitride film 31 is formed by nitriding the floating gate electrode 18 by anisotropic plasma nitriding in the above embodiment, a silicon oxide film may be formed by oxidizing the floating gate electrode film 18 by anisotropic plasma oxidation. Also in this case, the same shape as that of the above silicon nitride film 31 can be obtained, and the same effect as described above can be obtained. In this case, although a stacked structure obtained by stacking a silicon oxide film, a metal oxide film and a silicon oxide film in this order is formed as the inter-electrode insulating film 20, other stacked structures may be used. Any desired combination of silicon oxide films, silicon nitride films, and metal oxide films may be used as the stacked structure. For example, a stacked structure obtained by stacking a silicon oxide film, a silicon nitride film, and a silicon oxide film in this order may be used as the inter-electrode insulating film 20. Further, a stacked structure obtained by stacking a silicon oxide film, a silicon nitride film, a metal oxide film, a silicon nitride film, and a silicon oxide film in this order may be used as the inter-electrode insulating film 20. Furthermore, a stacked structure obtained by stacking a silicon oxide film, a silicon nitride film, a silicon oxide film, a silicon nitride film, and a silicon oxide film in this order may be used as the inter-electrode insulating film 20. In addition, the inter-electrode insulating film 20 may not be formed of a stacked structure, but may be a single-layer structure of a silicon oxide film. These structures can also obtain the same effect as described above.

Further, although the silicon nitride film 31 (or silicon oxide film) is formed by anisotropic plasma treatment in the above embodiment, the silicon nitride film 31 (or silicon oxide film) may be formed by other anisotropic treatment. For example, nitrogen (or oxygen) may be introduced into the surface region of the floating gate electrode film 18 by ion implantation, and heat treatment may be performed thereafter. Also in this case, it is possible to obtain a structure similar to the structure described in the above embodiment, and obtain the same effect as described above.

In addition, in the above embodiment and modifications, the silicon oxide film(s) may contain nitrogen. Further, the silicon nitride film(s) may contain oxygen.

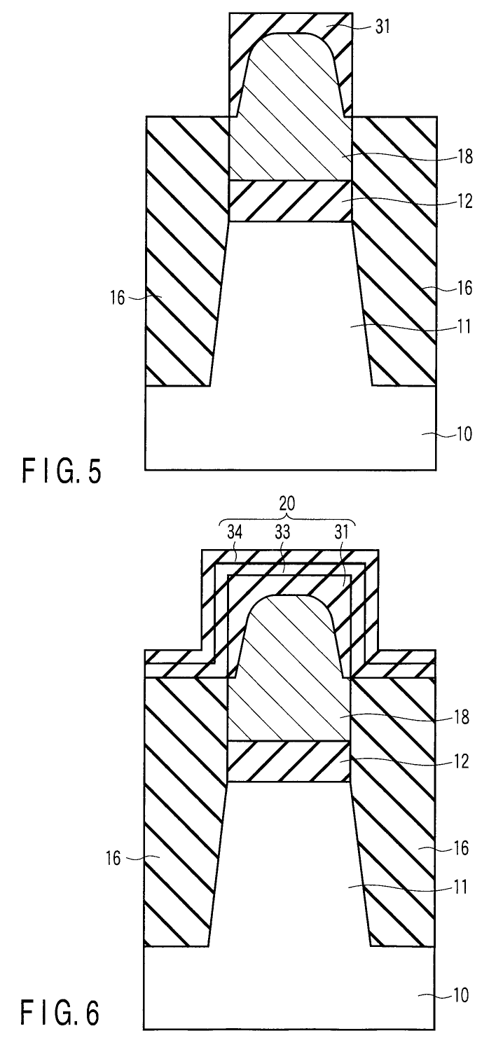

Although the basic shape (the shape before the inter-electrode insulating film 20 is formed) of the floating gate electrode 18 is not particularly referred to in the above embodiment, various basic shapes as illustrated in FIGS. 7A to 7D can be adopted. Also in these cases, the same effect as described above can be obtained.

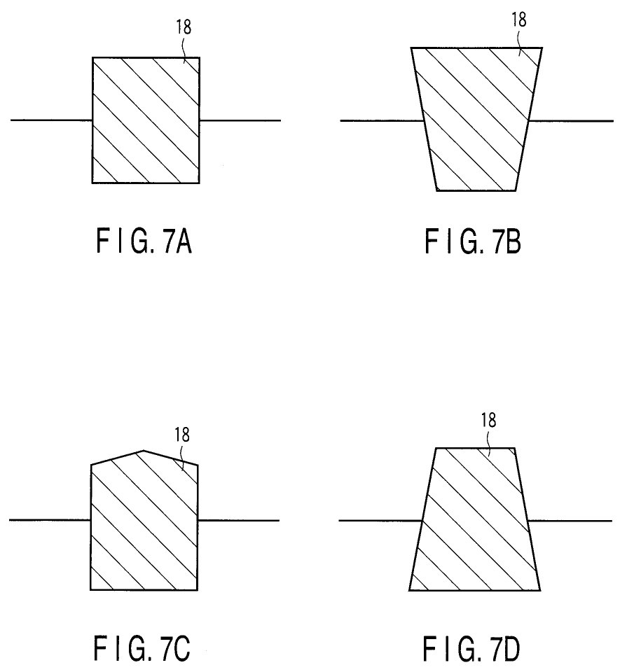

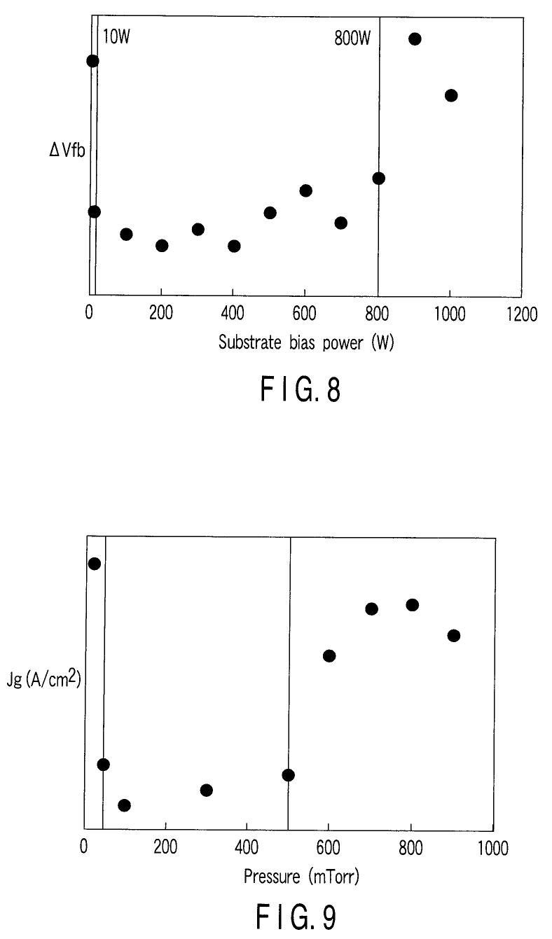

FIGS. 8 and 9 are diagrams illustrating measurement results obtained when the inter-electrode insulating film 20 is formed of a stacked structure including a silicon nitride film, a silicon oxide film, a metal oxide film, a silicon oxide film, and a silicon nitride film. The undermost silicon nitride film contacting the floating gate electrode is formed by anisotropic plasma nitriding as described in the above embodiment.

FIG. 8 is a diagram illustrating relationship between the substrate bias power in anisotropic plasma nitriding and the flat band voltage shift (ΔVfb). The vertical axis indicates the value of ΔVfb when 6×10⁵ seconds has passed since electric charge is accumulated in the floating gate electrode. As illustrated in FIG. 8, the value of ΔVfb is small in a range where the substrate bias power is 10 W to 800 W. Therefore, the substrate bias power preferably falls within the range of 10 W to 800 W.

FIG. 9 illustrates a diagram illustrating relationship between the pressure in chamber in anisotropic plasma nitriding and the leak current density Jg of the inter-electrode insulating film. As illustrated in FIG. 9, the value of Jg is small in a range where the pressure is 50 mTorr to 500 mTorr. Therefore, the pressure preferably falls within the range of 50 mTorr to 500 mTorr.

(Embodiment 2)

A semiconductor device (nonvolatile semiconductor memory device) according to a second embodiment of the present invention is described below. The semiconductor device is applied to, for example, NAND memories.

The basic manufacturing process of the semiconductor device according to the second embodiment is the same as the process illustrated in FIGS. 1 to 4 according to the first embodiment. Therefore, detailed explanation thereof is omitted.

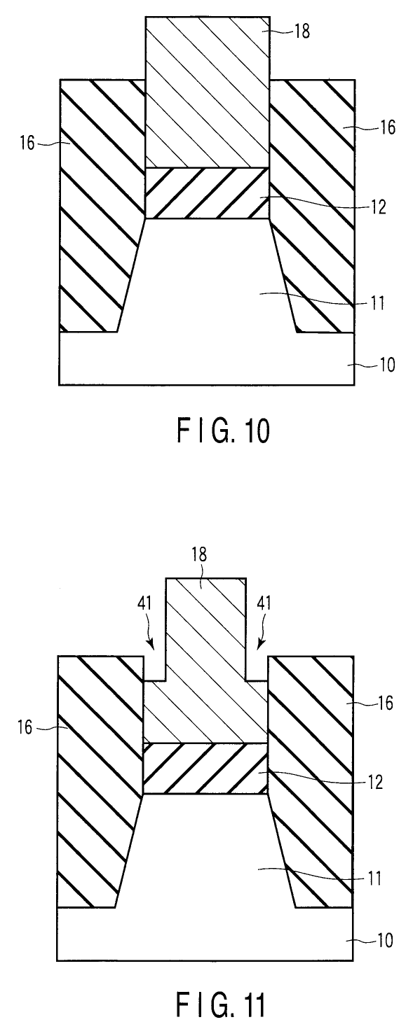

Details of a method of forming the inter-electrode insulating film 20 are explained with reference to cross-sectional views (cross-sectional views in the word line direction) of FIGS. 10 to 14.

First, the steps illustrated in FIGS. 1 to 3 are performed in the same manner as the first embodiment. FIG. 10 is a schematic diagram of a structure obtained after the step of FIG. 3 is finished.

Next, as illustrated in FIG. 11, a floating gate electrode film 18 is subjected to isotropic etching. In the isotropic etching, the floating gate electrode film 18 formed of polysilicon is selectively etched with respect to an isolation insulating film 16 formed of a silicon oxide film. Specifically, the floating gate electrode film 18 is etched by an alkaline etching solution such as ammonia solution. As a result, the width of an upper portion of the floating gate electrode film 18 is reduced, and trenches 41 are formed between the floating gate electrode film 18 and the isolation insulating film 16.

Next, as illustrated in FIG. 12, a silicon nitride film 42 is formed on the whole surface by using a film formation method with a good covering property. For example, a silicon nitride film 42 having a thickness of about 10 to 20 nm is formed by CVD (chemical vapor deposition). Thereby, the trenches 41 formed between the floating gate electrode film 18 and the isolation insulating film 16 are filled with the silicon nitride film 42. To securely fill the trenches 41 with the silicon nitride film 42, the silicon nitride film 42 is formed with a thickness larger than a target thickness.

Next, as illustrated in FIG. .13, the silicon nitride film 42 is etched to reduce the thickness of the silicon nitride film 42. Specifically, the silicon nitride film 42 is etched by using phosphoric acid heated to about 50 to 180° C. By this etching, the thickness of the silicon nitride film 42 is reduced to about 1 to 10 nm.

Next, as illustrated in FIG. 14, a metal oxide film (for example, an aluminum oxide film) 43 is formed on the silicon nitride film 42. Then, a silicon nitride film 44 is formed on the metal oxide film 43. Thereby, obtained is an inter-electrode insulating film 20 formed of a stacked film including the silicon nitride film (predetermined insulating film) 42, the metal oxide film 43, and the silicon nitride film 44. Thereafter, a control gate electrode film 21 is formed on the inter-electrode insulating film 20.

According to memory cells of a nonvolatile semiconductor memory device obtained as described above, the floating gate electrode 18 has a lower portion 18a formed on the tunnel insulating film, and an upper portion 18b having a width smaller than that of the lower portion 18a, as illustrated in FIG. 14. Further, the isolation insulating film 16 covers side surfaces of the device formation region 11, side surfaces of the tunnel insulating film 12, and side surfaces of the lower portion 18a of the floating gate electrode 18. The upper surface of the isolation insulating film 16 is located higher than a boundary 18c between the lower portion 18a and the upper portion 18b of the floating gate electrode 18. The boundary 18c is imaginary, and no actual boundary exists between the lower portion 18a and the upper portion 18b. The inter-electrode insulating film 20 covers the upper surface and side surfaces of the upper portion 18b of the floating gate electrode 18, and covers the upper surface of the isolation insulating film 16. Further, the inter-electrode insulating film 20 (in particular, the silicon nitride film 42) fills the trenches 41 (refer to FIG. 11) formed between the upper portion 18b of the floating gate electrode 18 and the isolation insulating film 16.

As described above, according to the second embodiment, the upper portion 18b of the floating gate electrode 18 has a width narrower than that of the lower portion 18a. Further, the region between the upper portion 18b of the floating gate electrode 18 and the isolation insulating film 16 is filled with the inter-electrode insulating film 20. Therefore, the thickness of the inter-electrode insulating film 20 (in particular, the silicon nitride film 42) substantially increases in the vicinity of upper corner portions of the isolation insulating film 16. In other words, the thickness of the inter-electrode insulating film 20 (in particular, the silicon nitride film 42) substantially increases in the vicinity of lower corner portions of the control gate electrode 21 at which the electric field tends to concentrate. As a result, it is possible to effectively prevent increase in the leak current and decrease in the breakdown voltage of the inter-electrode insulating film 20. Therefore, it is possible to improve the charge retention characteristic, and obtain a semiconductor device having excellent property and reliability.

The above second embodiment can be variously modified as described below.

Although the inter-electrode insulating film 20 is formed of a stacked structure including the silicon nitride film 42, the metal oxide film 43, and the silicon nitride film 44 in the above second embodiment, the inter-electrode insulating film 20 may be formed of other stacked structures. Any desired combination of silicon nitride films, silicon oxide films and metal oxide films can be used as the stacked structure. For example, a stacked structure obtained by stacking a silicon nitride film, a silicon oxide film, and a silicon nitride film in this order may be used as the inter-electrode insulating film 20. Further, a stacked structure obtained by stacking a silicon nitride film, a silicon oxide film, a metal oxide film, a silicon oxide film, and a silicon nitride film in this order may be used as the inter-electrode insulating film 20. Furthermore, a stacked structure obtained by stacking a silicon nitride film, a silicon oxide film, a silicon nitride film, a silicon oxide film, and a silicon nitride film in this order may be used as the inter-electrode insulating film 20. In these cases, the undermost silicon nitride film contacting the floating gate electrode film 18 corresponds to the silicon nitride film 42. Further, the inter-electrode insulating film 20 may not be formed of a stacked structure, but may be formed of a single-layer structure of the silicon nitride film 42. These structures can also obtain the same effect as described above.

Further, although the silicon nitride film 42 is formed as an insulating film contacting the floating gate electrode 18 in the above embodiment, a silicon oxide film may be formed instead of the silicon nitride film 42. Also in this case, it is possible to obtain a structure similar to that illustrated in FIG. 14, and obtain the same effect as described above. In this case, although a stacked structure obtained by stacking a silicon oxide film, a metal oxide film and a silicon oxide film in this order is formed as the inter-electrode insulating film 20, other stacked structures may be used. Any desired combination of silicon oxide films, silicon nitride films, and metal oxide films may be used as the stacked structure. For example, a stacked structure obtained by stacking a silicon oxide film, a silicon nitride film, and a silicon oxide film in this order may be used as the inter-electrode insulating film 20. Further, a stacked structure obtained by stacking a silicon oxide film, a silicon nitride film, a metal oxide film, a silicon nitride film, and a silicon oxide film in this order may be used as the inter-electrode insulating film 20. Furthermore, a stacked structure obtained by stacking a silicon oxide film, a silicon nitride film, a silicon oxide film, a silicon nitride film, and a silicon oxide film in this order may be used as the inter-electrode insulating film 20. In addition, the inter-electrode insulating film 20 may not be formed of a stacked structure, but may be a single-layer structure of a silicon oxide film. These structures can also obtain the same effect as described above.

In addition, in the above second embodiment and modifications, the silicon oxide film(s) may contain nitrogen. Further, the silicon nitride film(s) may contain oxygen.

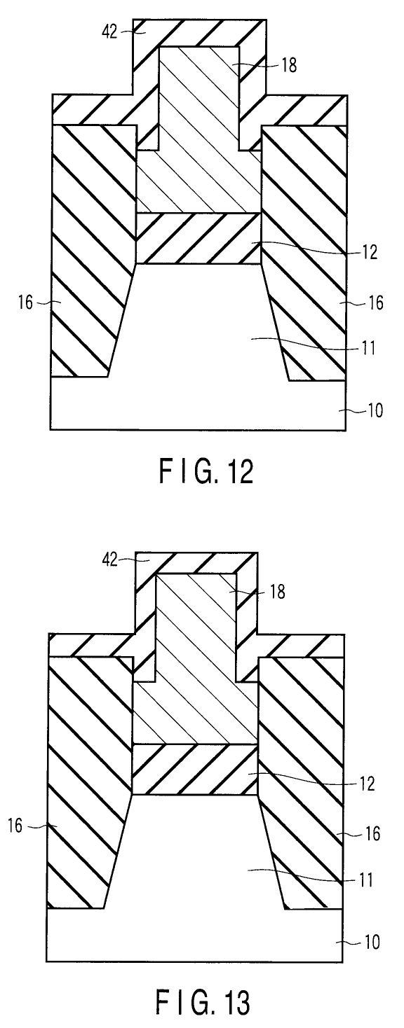

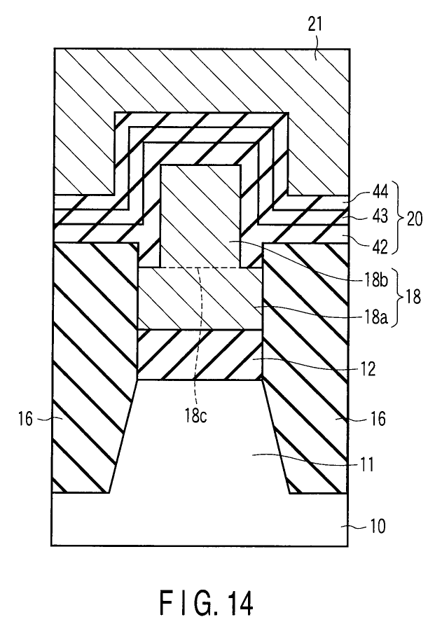

Further, although the shape of the trenches 41 formed by etching the floating gate electrode 18 is not particularly described, various shapes as illustrated in FIGS. 15 and 16 can be used. In the example illustrated in FIG. 15, the width of the trenches 41 is gradually narrowed from above downward. In the example illustrated in FIG. 16, the trenches expand in the vicinity of the bottom portions thereof. These structures can also obtain the same effect as described above.

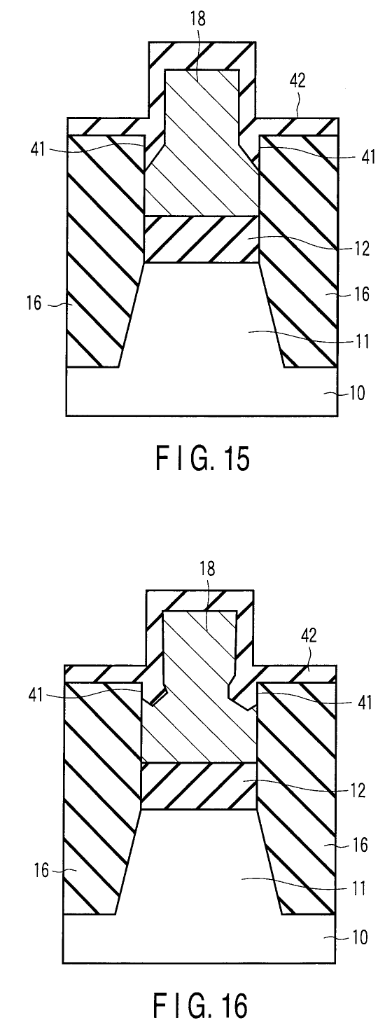

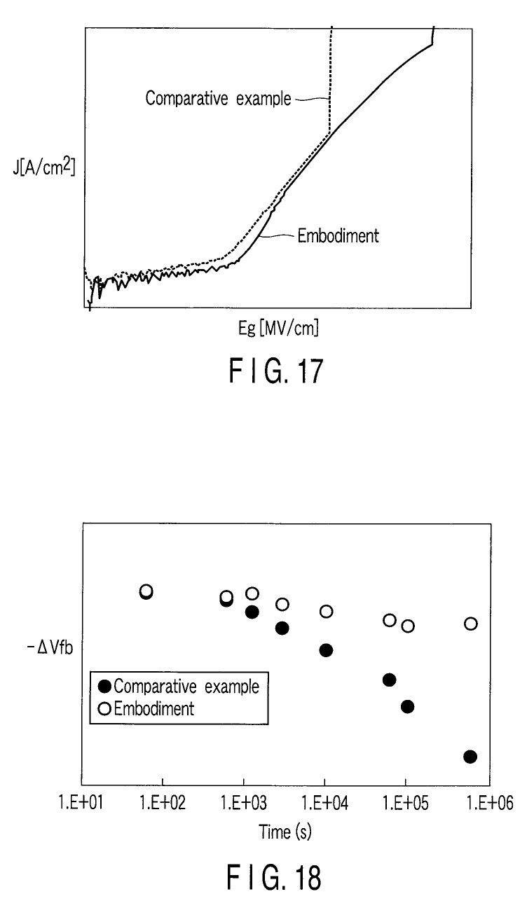

FIGS. 17 and 18 are diagrams illustrating measurement results obtained when the inter-electrode insulating film 20 is formed of a stacked structure including a silicon nitride film, a silicon oxide film, a metal oxide film, a silicon oxide film, and a silicon nitride film. Although the trenches 41 are formed in the sample of the second embodiment, no trenches 41 are formed in the sample of the comparative example.

FIG. 17 is a diagram illustrating relationship between the electric field Eg applied to the inter-electrode insulating film and the leak current density J of the inter-electrode insulating film. As is clear from FIG. 17, the leak current characteristic is greatly improved by adopting the structure of the second embodiment.

FIG. 18 is a diagram illustrating relationship between the time which has passed since the electric charge is accumulated in the floating gate electrode and the flat band voltage shift (ΔVfb). As is clear from FIG. 18, the value of ΔVfb does not much change even after lapse of time in the case where the structure of the second embodiment is adopted.

Therefore, it is also clear from the measurement results of FIGS. 17 and 18 that the structure of the second embodiment is effective.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate having a device formation region;
a tunnel insulating film formed on the device formation region;
a floating gate electrode formed on the tunnel insulating film;
isolation insulating films which cover side surfaces of the device formation region, side surfaces of the tunnel insulating film, and side surfaces of a lower portion of the floating gate electrode;
an inter-electrode insulating film which covers an upper surface and side surfaces of an upper portion of the floating gate electrode; and
a control gate electrode formed on the inter-electrode insulating film,
wherein upper corner portions of the floating gate electrode are rounded as viewed from a direction parallel with the upper surface and the side surfaces of the upper portion of the floating gate electrode.

2. A semiconductor device according to claim 1, wherein the inter-electrode insulating film includes a predetermined insulating film which contacts the floating gate electrode.

3. A semiconductor device according to claim 2, wherein the predetermined insulating film covers at least the upper corner portions of the floating gate electrode, and
a radius of curvature of the upper corner portions of the floating gate electrode is larger than a radius of curvature of upper corner portions of the predetermined insulating film.

4. A semiconductor device according to claim 2, wherein thickness of a portion of the predetermined insulating film, which is formed on the side surface of the floating gate electrode, increases from below upward.

5. A semiconductor device according to claim 2, wherein a portion of the predetermined insulating film, which is formed on the side surface of the floating gate electrode, is thinner than a portion of the predetermined insulating film, which is formed on the upper surface of the floating gate electrode.

6. A semiconductor device according to claim 2, wherein the predetermined insulating film is selected from an insulating film containing silicon and nitrogen as main components, an insulating film containing silicon and oxygen as main components, and an insulating film containing silicon, oxygen and nitrogen as main components.

7. A semiconductor device according to claim 2, wherein the inter-electrode insulating film further includes another insulating film formed on the predetermined insulating film.

8. A semiconductor device according to claim 7, wherein said another insulating film is formed of a metal oxide film.

9. A semiconductor device according to claim 1, wherein a radius of curvature of the upper corner portions of the floating gate electrode is larger than a radius of curvature of upper corner portions of the inter-electrode insulating film.

10. A semiconductor device comprising:
a semiconductor substrate having a device formation region;
a tunnel insulating film formed on the device formation region;
a floating gate electrode which is formed on the tunnel insulating film and has a lower portion and an upper portion having a width smaller than a width of the lower portion;
isolation insulating films which cover side surfaces of the device formation region, side surfaces of the tunnel insulating film, and side surfaces of the lower portion of the floating gate electrode, and has an upper surface located higher than a boundary between the lower portion and the upper portion of the floating gate electrode;
an inter-electrode insulating film which covers an upper surface and side surfaces of the upper portion of the floating gate electrode; and
a control gate electrode formed on the inter-electrode insulating film.

11. A semiconductor device according to claim 10, wherein the inter-electrode insulating film includes a predetermined insulating film which contacts the floating gate electrode.

12. A semiconductor device according to claim 11, wherein the predetermined insulating film fills a region between the upper portion of the floating gate electrode and the isolation insulating film.

13. A semiconductor device according to claim 11, wherein the predetermined insulating film is selected from an insulating film containing silicon and nitrogen as main components, an insulating film containing silicon and oxygen as main components, and an insulating film containing silicon, oxygen and nitrogen as main components.

14. A semiconductor device according to claim 11, wherein the inter-electrode insulating film further includes another insulating film formed on the predetermined insulating film.

15. A semiconductor device according to claim 14, wherein said another insulating film is formed of a metal oxide film.

16. A semiconductor device according to claim 10, wherein the inter-electrode insulating film fills a region between the upper portion of the floating gate electrode and the isolation insulating film.
